(19) United States
(12) Patent Application Publication
(10) Pub. No.: US 2025/0303427 A1
(43) Pub. Date: Oct. 2, 2025

(54) EVAPORATION SOURCE, DEPOSITION SYSTEM INCLUDING THE SAME, AND METHOD OF REPLACING EVAPORATION SOURCE

(71) Applicant: YAS CO. LTD., Paju-si (KR)

(72) Inventors: Su Hwan KIM, Paju-si (KR); Hyun Uk KANG, Paju-si (KR); Myung Woon CHOI, Paju-si (KR)

(73) Assignee: YAS CO. LTD., Paju-si (KR)

(21) Appl. No.: 19/063,665

(22) Filed: Feb. 26, 2025

(30) Foreign Application Priority Data
Mar. 29, 2024 (KR) 10-2024-0043075

(51) Int. Cl. B05B 1/14; B05B 1/04

(52) U.S. Cl. CPC B05B 1/14; B05B 1/04

(57) ABSTRACT

The present disclosure relates to an evaporation source, a deposition system including the same, and a method of replacing the evaporation source. An evaporation source according to one embodiment of the present disclosure includes a crucible having a cylinder shape and configured to accommodate a deposition material, and a nozzle member disposed on an upper end of the crucible, wherein the nozzle member includes a plurality of nozzle tips protruding from an upper surface of the nozzle member in a direction in which the deposition material is sprayed.

### CROSS-REFERENCE TO RELATED APPLICATION

This application claims priority to and the benefit of Korean Patent Application No. 10-2024-0043075, filed on Mar. 29, 2024, the disclosure of which is incorporated herein by reference in its entirety.

### BACKGROUND

### 1. Field of the Invention

The present disclosure relates to an evaporation source, a deposition system including the same, and a method of replacing the evaporation source, and more particularly, to an evaporation source for processing a substrate, a deposition system including the same, and a method of replacing the evaporation source.

### 2. Discussion of Related Art

When semiconductors, displays such as liquid crystal displays (LCDs) and organic light-emitting diodes (OLEDs), lights, solar cells, and the like are manufactured, evaporation sources are used to spray a deposition material toward a substrate. An evaporation source may include a crucible for accommodating a deposition material, a heater for heating the crucible, and a nozzle through which a material is sprayed. Representative evaporation sources include linear evaporation sources that extend in a longitudinal direction and point evaporation sources that spray a deposition material onto a specific region.

Meanwhile, as the demand for large-area displays, solar cells, and the like has increased recently, there is also a need to develop process technologies for processing large-area substrates. Accordingly, technologies capable of uniformly depositing a deposition material on a large-area substrate are being researched. Among the technologies, a technology has been proposed to perform deposition on a large-area substrate using a plurality of evaporation sources without degradation in the thickness uniformity of a thin film. When a plurality of evaporation sources are used, a method of setting output power of some evaporation sources differently may be used to prevent a degradation problem in the thickness uniformity of a thin film on a substrate.

However, when output power of some evaporation sources is different, a difference in residual amount between deposition materials accommodated in a plurality of evaporation sources may gradually occur. When there is a difference in residual material between a plurality of evaporation sources, a shape in which a deposition material is sprayed from each evaporation source may become unstable, or a spray amount may be different. Accordingly, according to the related art, there is a problem in which the thickness uniformity of a thin film gradually degrades as a substrate deposition process progresses.

In addition, when a defect occurs in any one of a plurality of evaporation sources, there may be a problem in degradation in the thickness uniformity of a thin film of a substrate. For example, when a clogging phenomenon occurs in one evaporation source, a thin film of a region onto which the evaporation source having the clogging phenomenon sprays a deposition material may gradually become thinner.

Accordingly, there is a need to develop a technology capable of performing deposition on a large-area substrate with high thickness uniformity of a thin film using a plurality of evaporation sources and maintaining excellent thickness uniformity of a thin film even in the last stage of a process by not allowing a deposition material contained in each evaporation source to be consumed differently. Meanwhile, the information in the background art described above was obtained by the inventors for the purpose of developing the present disclosure or was obtained during the process of developing the present disclosure. As such, it is to be appreciated that this information did not necessarily belong to the public domain before the patent filing date of the present disclosure.

### RELATED ART DOCUMENTS

### Patent Documents

(Patent Document 1) Korean Patent Publication No. 10-2017-0056375 (May 23, 2017).

### SUMMARY OF THE INVENTION

The present disclosure is directed to providing an evaporation source capable of depositing a thin film on a large-area substrate with excellent thickness uniformity, a deposition system including the same, and a method of replacing the evaporation source.

The present disclosure is also directed to providing an evaporation source in which a reduction rate of a deposition material between evaporation sources is maintained uniformly so that the thickness uniformity of a thin film does not degrade even in the last state of a process, a deposition system including the same, and a method of replacing the evaporation source.

The present disclosure is also directed to providing an evaporation source in which evaporation sources each including nozzles, in which a thin film deposited on a substrate has the same thickness profile, are provided so that, even when a defect occurs in any one of the evaporation sources, the thickness uniformity of the thin film of the substrate is not degraded, a deposition system including the same, and a method of replacing the evaporation source.

The objects of the present disclosure are not limited to those described above, and other objects not described may become apparent to those of ordinary skill in the art based on the following descriptions.

According to an aspect of the present disclosure, there is provided an evaporation source including a crucible having a cylinder shape and configured to accommodate a deposition material, and a nozzle member disposed on an upper end of the crucible, wherein the nozzle member includes a plurality of nozzle tips protruding from an upper surface of the nozzle member in a direction in which the deposition material is sprayed.

A spray angle, which is defined as an angle between a protruding direction of each of the plurality of nozzle tips and a direction perpendicular to the upper surface of the nozzle member, and a position of each of the plurality of nozzle tips may be determined such that a thickness profile of a thin film, which is formed by depositing the deposition material sprayed through the plurality of nozzle tips on a substrate, becomes uniform.

The spray angles of at least two of the plurality of nozzle tips may be different.

Protruding directions of the plurality of nozzle tips may be positioned on one plane.

The plurality of nozzle tips may be arranged in a line on the upper surface of the nozzle member.

At least one of the plurality of nozzle tips may be disposed in a different column from columns in which other nozzle tips are arranged.

Opening areas of the plurality of nozzle tips may be equal to each other, and the opening area may be an area of a cross section perpendicular to a protruding direction of each of the plurality of nozzle tips.

Opening areas of at least two of the plurality of nozzle tips may be different, and the opening area may be an area of a cross section perpendicular to a protruding direction of each of the plurality of nozzle tips.

According to another aspect of the present disclosure, there is provided a deposition system for depositing a deposition material on a substrate, the deposition system including an evaporation source including a plurality of nozzle tips configured to spray a deposition material toward a plurality of target regions, wherein a spray angle of at least one of the plurality of nozzle tips is set to spray the deposition material toward a target region different from a target region onto which other nozzle tips spray the deposition material.

The evaporation source may be provided as a plurality of evaporation sources, and each of the plurality of evaporation sources may be heated with the same power to evaporate the deposition material.

The spray angles of at least two of the plurality of evaporation sources may be equal to each other.

The spray angle of each of the plurality of nozzle tips may be determined according to Equation 1 below:

$$θ = {tan}^{- 1} ( \frac{{x}_{e} - {x}_{t}}{L} ) \qquad [ Equation 1 ]$$

wherein θ denotes the spray angle which is an angle between a protruding direction of the nozzle tip and a direction perpendicular to an upper surface of the evaporation source including the nozzle tip, xₑ denotes an x-axis coordinate at which the evaporation source is positioned on a plane including a central axis and the evaporation source, xₜ is denotes an x-axis coordinate at which a target point is positioned on a plane including the central axis and the evaporation source, and L denotes a distance between the evaporation source and the substrate.

An opening area of each of the plurality of nozzle tips may be determined based on an angular velocity for a rotation of the substrate and the spray angle and may be an area of a cross section perpendicular to the protruding direction of the nozzle tip.

According to still another aspect of the present disclosure, there is provided a method of replacing an evaporation source, the method including depositing a deposition material on a rotating substrate using an existing evaporation source, measuring a thickness profile of a thin film formed on the substrate, determining a region, for which supplementation of a thickness of the thin film is required, based on the thickness profile, and replacing the existing evaporation source with a new evaporation source including a plurality of nozzle tips configured to spray the deposition material, wherein the plurality of nozzle tips are set to thickly deposit the deposition material on the region for which supplementation is required so that a film thickness of the region, for which supplementation is required, and other regions become uniform.

When a region deposited on the substrate to be the thickest is positioned at a central portion of the substrate, the replacing may include setting a spray angle of the replacing evaporation source such that at least one of the plurality of nozzle tips sprays the deposition material toward the outside of the substrate.

When a region deposited on the substrate to be the thickest is positioned in an inner region of the substrate rather than a central portion of the substrate, the replacing may include setting a spray angle of the replacing evaporation source such that at least two of the plurality of nozzle tips spray the deposition material toward the central portion of the substrate and the outside of the substrate, respectively.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a perspective view of an evaporation source according to one embodiment of the present disclosure;

FIG. 2 is a perspective view of an evaporation source according to another embodiment of the present disclosure;

FIG. 3 is a perspective view of an evaporation source according to still another embodiment of the present disclosure;

FIG. 4 is a perspective view of an evaporation source according to yet another embodiment of the present disclosure;

FIG. 5 is a view for describing a deposition system according to one embodiment of the present disclosure;

FIG. 6 is a view for describing a spray angle of a nozzle tip for spraying a deposition material toward a target point according to one embodiment of the present disclosure;

FIG. 7 is a flowchart of a method of replacing an evaporation source according to one embodiment of the present disclosure;

FIG. 8 is a view for describing a spray direction of a replacing evaporation source when a thick region is positioned in a central region;

FIG. 9 is a view for describing a spray direction of a replacing evaporation source when a thick region is positioned in an inner region; and

FIG. 10 is a view for describing a spray direction of a replacing evaporation source when a thick region is positioned in an outer region.

### DETAILED DESCRIPTION OF EXEMPLARY EMBODIMENTS

The advantages and features of the present disclosure and methods of accomplishing the same will become apparent from the following description of the embodiments in detail, taken in conjunction with the accompanying drawings. However, the present disclosure is not limited to the embodiments to be disclosed below and may be implemented in various different forms. The present embodiments are merely provided so that this disclosure will be complete and will fully convey the scope of the invention to those skilled in the art. That is, the present disclosure is only defined by the scope of the claims.

A shape, a size, a ratio, an angle, and a number disclosed in the drawings for describing embodiments of the present disclosure are merely an example, and thus, the present disclosure is not limited to the illustrated details. In addition, in describing the present disclosure, when it is determined that the specific description of the known related art unnecessarily obscures the gist of the present disclosure, the detailed description thereof will be omitted. The terms such as “including,” “having,” and “consist of” used herein are generally intended to allow other components to be added unless the terms are used with the term “only.” Any references to singular may include plural unless expressly stated otherwise.

Components are interpreted to include an ordinary error range even if not expressly stated. For example, unless otherwise explicitly stated, the term “same” does not mean exactly the same, but rather means “substantially the same” within a margin of error that a person skilled in the art may reasonably expect to encounter in practicing the present disclosure.

Although the terms first, second, and the like are used to describe various components, these components are not limited by these terms. These terms are merely used to distinguish one component from another. Therefore, a first component to be described below may be a second component in a technical concept of the present disclosure.

Unless otherwise specified, like reference numerals refer to like elements throughout the specification.

The features of various embodiments of the present disclosure can be partially or entirely adhered to or combined with each other and can be interlocked and operated in technically various ways as understood by those skilled in the art, and the embodiments can be carried out independently of or in association with each other.

In the present disclosure, when a plurality of components are connected, it should be understood that the components are connected not only directly to each other, but also indirectly connected to each other. Therefore, when a plurality of components are connected to each other, another component may be connected between the plurality of components.

In describing various embodiments of the present disclosure, when some components of an embodiment are substantially the same as or corresponding to some components of another embodiment described above, the description of the components may be omitted for a clear and concise description of the present disclosure. In addition, when some components have a symmetry structure with other components, for example, an axial symmetry structure or a rotational symmetry structure so that both components are substantially the same component but only differ in direction or position, unless it is necessary to specify the present disclosure, descriptions of the components may be omitted for the sake of a clear and concise description of the present disclosure.

Hereinafter, the present disclosure will be described in detail with reference to the accompanying drawings.

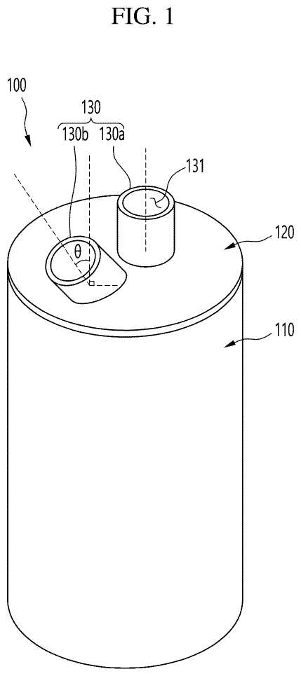

FIG. 1 is a perspective view of an evaporation source according to one embodiment of the present disclosure.

Referring to FIG. 1, an evaporation source 100 may spray a deposition material to be deposited on a substrate.

The evaporation source 100 may be disposed below the substrate (not shown). When the substrate (not shown) is tilted, an arrangement position of the evaporation source 100 may be determined based on a direction in which the evaporation source 100 sprays a deposition material and an angle at which the substrate is tilted.

The evaporation source 100 may have a cylinder shape. That is, the evaporation source 100 may have a cylindrical shape. Accordingly, the evaporation source 100 may be a point evaporation source.

The evaporation source 100 includes a crucible 110 and a nozzle member 120 arranged on an upper end of the crucible 110. In addition, the evaporation source 100 may further include a housing (not shown) or a heater (not shown).

The crucible 110 accommodates a deposition material. A space for accommodating a deposition material may be formed inside the crucible 110.

The crucible 110 may be disposed at a lower portion of the evaporation source 100.

The crucible 110 has a cylinder shape. That is, the crucible 110 has a cylindrical shape. Specifically, a shape of a cross section of the crucible 110 perpendicular to a height shape.

direction is a circular shape.

An opening (not shown) for coupling to the nozzle member 120 may be formed in an upper surface of the crucible 110. Here, the opening (not shown) of the crucible 110 may also function as a portion of a flow path through which an evaporated deposition material is sprayed.

The crucible 110 may be connected or coupled to various structures. For example, the housing (not shown) may be provided to accommodate the crucible 110, protect the crucible 110 from external impacts and contaminants, and prevent heat from being emitted to the outside of the evaporation source. In addition, the crucible 110 may be a structure formed by coupling a plurality of structures into one.

In addition, the crucible 110 may receive heat generated by the heater (not shown).

The heater (not shown) may transfer heat to the crucible 110 to heat a deposition material accommodated inside the crucible 110. The heater (not shown) may be in contact with the crucible 110, may be spaced apart from and adjacent to the crucible 110, or may be inserted into a sidewall of the crucible 110. In addition, the heater (not shown) may surround at least a portion of a side surface of the crucible 110 and may be disposed at an upper or lower side of the crucible 110.

The heater (not shown) may be implemented in various manners such as a resistance heating manner or an induction heating manner. For example, the heater may include at least one heating wire that emits heat in a resistive heating manner.

The nozzle member 120 functions as an outlet for discharging a deposition material vaporized and heated by the crucible 110 to a substrate.

The nozzle member 120 is disposed on the upper end of the crucible 110. The nozzle member 120 may include a plate-shaped member covering the upper end of the crucible 110 and a plurality of nozzle tips 130 formed to protrude upward from the plate-shaped member.

The plate-shaped member of the nozzle member 120 may have a circular shape corresponding to a cross-sectional shape of the crucible 110 and may have a larger area than the opening formed in the upper end of the crucible 110. However, the present disclosure is not limited thereto, and the plate-shaped member of the nozzle member 120 may be implemented in one of various shapes such as a polygonal shape or an oval shape.

The nozzle member 120 may be coupled to the crucible 110 in various ways. For example, the nozzle member 120 may be coupled to the crucible 110 through screw threads, may be inserted into and coupled to the opening of the crucible 110, or may be coupled by a protrusion formed on an inner surface of the crucible 110 being caught by a groove formed in the nozzle member 120. Alternatively, the crucible 110 and the nozzle member 120 may be formed integrally.

Referring to FIG. 1, the nozzle member 120 includes the plurality of nozzle tips 130. For example, the nozzle member 120 may include a first nozzle tip 130a and a second nozzle tip 130b. The plurality of nozzle tips 130 may function as a flow path through which a vaporized deposition material is sprayed.

The plurality of nozzle tips 130 may be formed integrally with the nozzle member 120, and each of the plurality of nozzle tips 130 may be inserted into one of a plurality of hollows formed to pass through the nozzle member 120.

The plurality of nozzle tips 130 may have different shapes. For example, among the plurality of nozzle tips 130, a shape of a cross section of any one nozzle tip perpendicular to a longitudinal direction may be a circular shape, and a shape of a cross section of another nozzle tip perpendicular to the longitudinal direction may be an oval shape or a polygonal shape. In addition, the plurality of nozzle tips 130 may also have different heights.

Each of the plurality of nozzle tips 130 may have a hollow tube shape, and an opening 131 may be formed in an end portion of each of the plurality of nozzle tips 130. A space formed inside each of the plurality of nozzle tips 130 may function as a discharge path that guides an evaporated deposition material to head in a specific direction. Accordingly, an evaporation material accommodated in the crucible 110 may be evaporated and moved toward an upper side of the crucible 110 and may be sprayed in a protruding direction of each of the plurality of nozzle tips 130 through the discharge path and the opening 131 formed in each of the plurality of nozzle tips 130.

Meanwhile, a space formed inside each of the plurality of nozzle tips 130 may have various shapes. Specifically, a cross-sectional area of the space, which is formed inside each of the plurality of nozzle tips 130, perpendicular to a longitudinal direction, may be constant and may gradually increase or decrease in some cases. For example, the space formed inside each of the plurality of nozzle tips 130 may have a truncated cone shape.

The plurality of nozzle tips 130 protrude from an upper surface of the nozzle member 120 in a direction in which a deposition material is sprayed. That is, a protruding direction of the nozzle tip 130 may be the same as a direction in which the nozzle tip 130 sprays a deposition material. In this case, a spray angle θ at which each of the plurality of nozzle tips 130 sprays a deposition material may be determined such that a thickness profile of a thin film formed by depositing the deposition material, which is sprayed through the plurality of nozzle tips 130, on the substrate, becomes uniform. Here, the spray angle θ may be defined as an angle between the protruding direction of each of the plurality of nozzle tips 130 and a direction perpendicular to the upper surface of the nozzle member 120.

Spray angles of the plurality of nozzle tips 130 may each independently be set. That is, the spray angles of the plurality of nozzle tips 130 may be the same or different. In addition, the spray angles of at least two of the plurality of nozzle tips 130 may be different. For example, the spray angle of the first nozzle tip 130a may have a value of 0, and the spray angle θ of the second nozzle tip 130b may have a value greater than 0.

According to the above-described embodiment, the nozzle member 120 may include the plurality of nozzle tips 130 having different spray angles so that the evaporation source 100 may simultaneously cover various target regions on which a deposition material is to be deposited. For example, the first nozzle tip 130a of the nozzle member 120 may cover a first target region of a substrate corresponding directly to an upper portion of the evaporation source 100, and the second nozzle tip 130b may cover a second target region spaced apart from the first target region of the substrate according to a spray angle tilted by θ.

The openings 131 of the first nozzle tip 130a and the second nozzle tip 130b may have the same area. Here, an opening area is an area of a cross section of each of the plurality of nozzle tips 130 perpendicular to the protruding direction. In this case, since the first nozzle tip 130a and the second nozzle tip 130b are provided on the same one crucible 110, deposition materials sprayed through the first nozzle tip 130a and the second nozzle tip 130b may be sprayed in substantially the same amount. When a substrate rotates, angular velocities of the first target region and the second target region among regions of the substrate may be different. In this case, even when deposition materials are sprayed in the same amount from the nozzle tips 130, thicknesses of thin films deposited on the first target region and the second target region may be different.

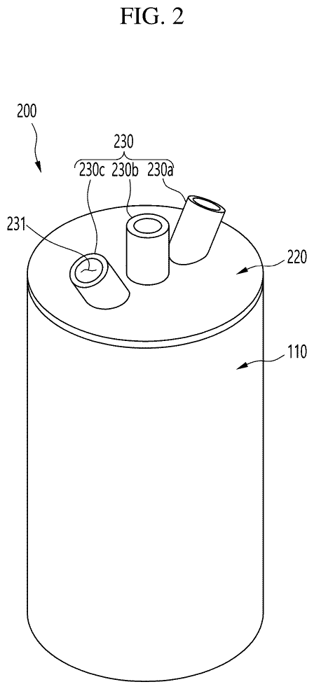

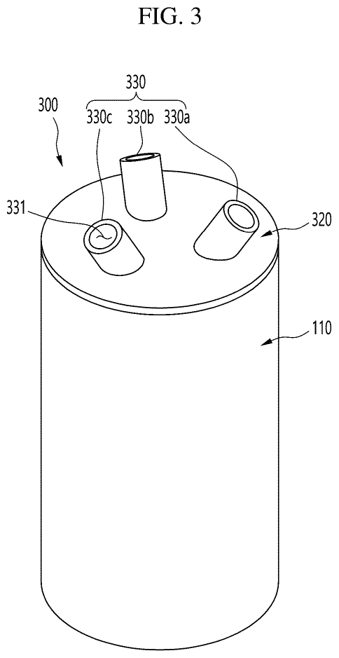

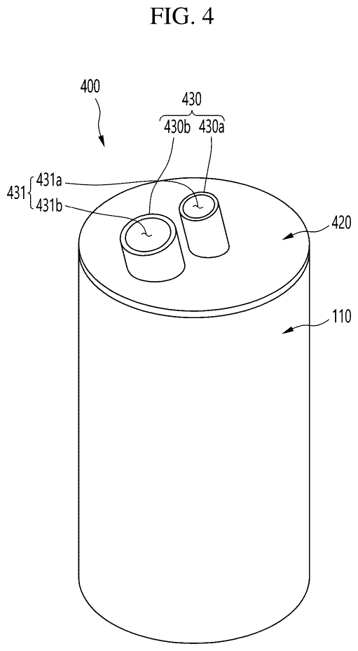

FIG. 2 is a perspective view of an evaporation source according to another embodiment of the present disclosure. FIG. 3 is a perspective view of an evaporation source according to still another embodiment of the present disclosure. FIG. 4 is a perspective view of an evaporation source according to yet another embodiment of the present disclosure. The evaporation sources 200, 300, and 400 of FIGS. 2 to 4 are different from the evaporation source 100 of FIG. 1 in only nozzle tips 230, 330, and 430 of nozzle members 220, 320, and 420, except that remaining components are the same as those of the evaporation source 100, and thus redundant descriptions will be omitted.

Referring to FIG. 2, the number of nozzle tips 230 provided on the nozzle member 220 is three. The number of nozzle tips 230 may be determined to correspond to the number of target regions of a substrate. For example, when three target regions to be covered by the evaporation source 200 are provided, the evaporation source 200 may include three nozzle tips 230.

An area of an opening 231 of each of a plurality of nozzle tips 230 shown in FIG. 2 may be smaller than an area of the opening 131 of each of the plurality of nozzle tips 130 shown in FIG. 1. Accordingly, since the number of the nozzle tips 230 shown in FIG. 2 is greater than the number of the nozzle tips 130 shown in FIG. 1, but each of the nozzle tips 230 has a smaller area than each of the nozzle tips 130, the total amount of a deposition material sprayed by the evaporation source 200 shown in FIG. 2 may be substantially the same as the total amount of a deposition material sprayed by the evaporation source 100 shown in FIG. 1.

The plurality of nozzle tips 230 may be arranged in a line on the nozzle member 220 and may protrude in different directions. In this case, protruding directions of the plurality of nozzle tips 230 may be positioned on one plane. Here, the expression “positioned one plane” may mean that vectors of the protruding directions of the plurality of nozzle tips 230 are disposed on one plane.

In this way, when the plurality of nozzle tips 230 protrude in different directions and are positioned on one plane, the evaporation source 200 may spray a deposition material toward target regions positioned on a plane that includes a center of the evaporation source 200 and a center of a substrate. In this case, a distance by which a deposition material sprayed by the evaporation source 200 moves toward the target region may be minimized. Accordingly, the deposition efficiency of the evaporation source 200 can be improved, and the accuracy with which a sprayed deposition material is seated on the target region can be improved.

Referring to FIG. 3, a plurality of nozzle tips 330 may not be arranged in a line on the nozzle member 320. That is, at least one of the plurality of nozzle tips 330 may be disposed in a different column from a column in which other nozzle tips are disposed. In addition, protruding directions of the plurality of nozzle tips 330 may not be positioned on one plane.

In this case, deposition materials sprayed by the plurality of nozzle tips 330 may be occluded from each other or may overlap each other to not be deposited. Accordingly, according to the above-described embodiment, the detection accuracy of a quartz crystal monitor (QCM) sensor can be improved. Here, the QCM sensor is a device that senses a thickness of a thin film or a deposition speed of a deposition material deposited on a substrate in real time.

Referring to FIG. 4, an area of an opening 431a of a first nozzle tip 430a may be different from an area of an opening 431b of a second nozzle tip 430b. In this way, by setting an opening area of each nozzle tip 430 differently, a speed at which a thin film is deposited on a target region covered by each nozzle tip 430 may be set differently. Accordingly, since the evaporation source 400 may control an amount of a deposition material sprayed onto each target region, the thickness uniformity of a thin film deposited on a substrate can be improved.

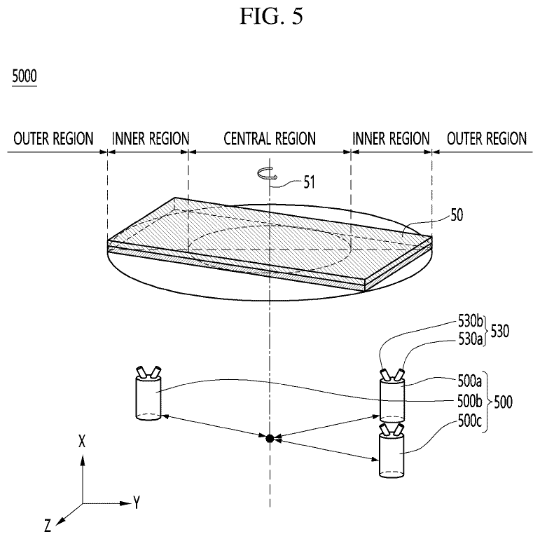

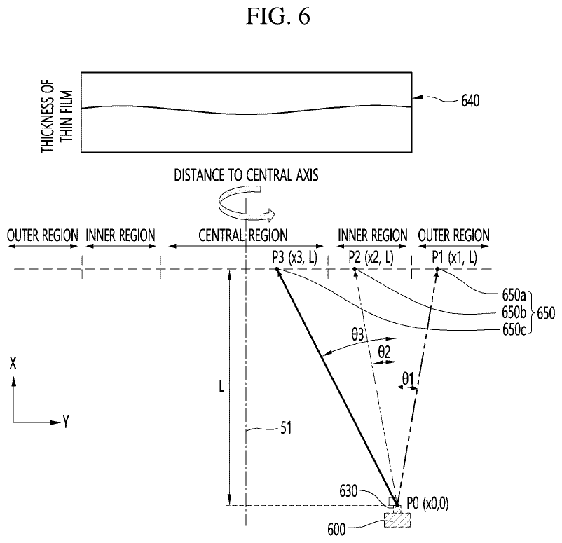

FIG. 5 is a view for describing a deposition system according to one embodiment of the present disclosure. FIG. 6 is a view for describing a spray angle of a nozzle tip for spraying a deposition material toward a target point according to one embodiment of the present disclosure.

Referring to FIG. 5, a deposition system 5000 includes an evaporation source 500 including a plurality of nozzle tips 530 for spraying a deposition material. The deposition system 5000 is a system for depositing a deposition material on a substrate 50 using the evaporation source 500. The deposition system 5000 may include various components (not shown) for supporting the substrate 50.

The substrate 50 may be a plate-shaped structure used in semiconductor devices, display panels including liquid crystal displays (LCDs) and organic light-emitting diodes (OLEDs), lighting devices, solar cells, and the like.

The substrate 50 may rotate around a central axis 51. An angular velocity of the rotating substrate 50 may be various, and the substrate 50 may also rotate while tilting in one direction. The deposition system 5000 may include various structures that support and rotate the substrate 50.

The substrate 50 may have various shapes. For example, the substrate 50 may have a quadrangular shape, a polygonal shape, or a circular shape. In addition, the substrate 50 may have a shape that is curved at a certain angle.

The evaporation source 500 may be disposed in a specific region of the deposition system 5000 to be spaced apart from the substrate 50 and may be provided as a plurality of evaporation sources 500.

The evaporation sources 500 may be disposed to be spaced a certain distance apart from the central axis 51 of the substrate 50, and distances by which two or more of the plurality of evaporation sources 500 are spaced apart from the central axis 51 may be equal to each other.

Each of the evaporation sources 500 includes the plurality of nozzle tips 530, and each nozzle tip 530 sprays a deposition material toward a target region. Specifically, the deposition material is sprayed through the nozzle tip 530 of the evaporation source 500 and deposited on a target region faced by the nozzle tip 530. In this case, the deposition material may be sprayed radially from the nozzle tip 530. Accordingly, when an area of the substrate is sufficiently small, the deposition material sprayed from one nozzle tip 530 can cover the entire area of the substrate 50, but in the case of the substrate 50 with a large area, the deposition material sprayed from the nozzle tip 530 can cover only a specific region of the substrate 50.

As described above, since the substrate 50 is provided to rotate around the central axis 51 of the substrate 50, a target region covered by a deposition material sprayed from the nozzle tip 530 may be formed in a circle or donut shape according to the rotation of the substrate 50.

In the present disclosure, the target region related to a spray angle of the nozzle tip 530 may be divided into a central region, an inner region, and an outer region.

Specifically, when the nozzle tip 530 sprays a deposition material toward the central axis 51 of the substrate 50, a first target region covered by the deposition material sprayed from the nozzle tip 530 may correspond to a circular region including a center point of the substrate 50 and may be defined as the central region. For example, the central region may be a circular region including the central axis 51 as a center and having a diameter equal to a length of a short side of the substrate 50 in a circular trajectory drawn by vertices of the substrate 50 as the substrate 50 rotates around the central axis 51. That is, a circular region in which a portion of the substrate 50 always exists while the substrate 50 rotates may be defined as the central region.

On the other hand, when the nozzle tip 530 sprays the deposition material toward a specific region spaced apart from the central axis 51 of the substrate 50, the deposition material sprayed from the nozzle tip 530 may be deposited on a second target region having a donut shape surrounding the central region according to the rotation of the substrate 50, and the second target region is defined as the inner region. For example, the inner region may be a circular region including the central axis 51 as a center and having a diameter equal to a length of a diagonal side of the substrate 50 in a circular trajectory drawn by vertices of the substrate 50 as the substrate 50 rotates around the central axis 51. That is, a region in which a portion of the substrate 50 repeatedly exists and disappears while the substrate 50 rotates may be defined as the inner region.

Meanwhile, when the nozzle tip 530 sprays the deposition material toward the outside of the inner region, a region onto which the nozzle tip 530 sprays the deposition material is defined as the outer region. The outer region is a region in which the substrate 50 does not exist or a region in which the deposition material may be deposited on a partial region of the substrate 50 as the deposition material is sprayed radially from the nozzle tip 530.

Since the above-described central region, inner region, and outer region are classified according to the characteristics in which the deposition material is deposited on the substrate 50, when a spray angle of the nozzle tip 530 is determined according to the classifications, it can be easy to design the deposition system 5000 for uniformizing a thickness profile of a thin film.

Meanwhile, in the deposition system 5000, the number of nozzle tips 530 of the evaporation source 500, the spray angle of the nozzle tip 530, and the opening area of the nozzle tip 530 are determined such that a thickness profile of a thin film formed by the deposition material sprayed through the plurality of nozzle tips 530 being deposited on the substrate 50 becomes uniform.

Referring to FIG. 6, a spray angle of a nozzle tip 630 may be determined such that a thin film thickness profile 640 of a substrate becomes uniform. Here, the thin film thickness profile 640 may be acquired by a QCM sensor or a separate sensor and optical device and may also be acquired using data simulated by a processor (not shown). Specifically, in the thin film thickness profile 640, a region for which supplementation of a thickness of a thin film thickness is required may be determined as a target region, and a portion of the target region in which a thin film is the thinnest may be determined as a target point 650. In addition, a spray angle may be set such that the nozzle tip 630 sprays a deposition material toward the target point 650.

A spray angle θ of each of a plurality of nozzle tips 630 may be determined according to Equation 1 below. Here, the spray angle θ is an angle between a protruding direction of the nozzle tip 630 and a direction perpendicular to an upper surface of an evaporation source 600 including the nozzle tip 630.

$$θ = {tan}^{- 1} ( \frac{{x}_{e} - {x}_{t}}{L} ) \qquad [ Equation 1 ]$$

Here, xₑ denotes an x-axis coordinate at which the evaporation source 600 is positioned on a plane including a central axis 51 and the evaporation source 600, xₜ denotes an x-axis coordinate at which the target point 650 is positioned on the plane including the central axis 51 and the evaporation source 600, and L denotes a distance between the evaporation source 600 and a substrate.

In addition, when a direction in which the evaporation source 600 sprays the deposition material is tilted toward the central axis 51, a sign of the spray angle θ may be +, and when the direction in which the evaporation source 600 sprays the deposition material is tilted in a direction opposite to the central axis 51, the sign of the spray angle θ may be −. For example, a spray angle θ₃ determined according to Equation 1 for the evaporation source 600 to spray the deposition material toward a target point P3 (650c) may be

$${tan}^{- 1} ( \frac{{x}_{o} - {x}_{s}}{L} ) .$$

According to the above-described embodiment, in a coordinate system including the central axis 51 and the evaporation source 600, the spray angle θ of the evaporation source 600 may be determined only with coordinates of the target point 650 and the evaporation source 600, and thus it may be easy to improve the thickness uniformity of a thin film of a substrate.

For example, when only the nozzle tip 630 for spraying a deposition material toward an inner region is provided in the evaporation source 600, a thin film deposited on the inner region may become thicker as in the thin film thickness profile 640. In such a case, a center-drop phenomenon may occur in which a thin film becomes thinner in a central region of the substrate. In this case, according to a deposition system of the present disclosure, a central region, which is a region for which supplementation of the thin film thickness profile 640 is required, is determined to be the target region, and the nozzle tip 630, of which a spray angle θ is set to be directed toward a portion at which a thin film is the thinnest, may be additionally disposed, thereby improving the thickness uniformity of the thin film.

Meanwhile, the spray angle θ of the nozzle tip 630 may be determined according to Equation 2 below.

$$θ = {tan}^{- 1} ( \frac{{x}_{e} - {x}_{t}}{L} ) + a \qquad [ Equation 2 ]$$

Here, a may be determined based on a tilt angle of the substrate and a weight for a thickest portion of the thin film. According to the above-described embodiment, since the spray angle θ is determined in consideration of the tilt of the substrate and coordinates of the thickest portion of the thin film, the deposition system 5000 can further improve the thickness uniformity of the thin film of the substrate.

Referring again to FIG. 5, in the deposition system 5000, the plurality of nozzle tips 530 spray a deposition material toward a plurality of target regions. In addition, a spray angle of at least one of the plurality of nozzle tips 530 is set to spray the deposition material toward a target region different from a target region onto which other nozzle tips spray the deposition material.

For example, a spray angle of the first nozzle tip 530a in a first evaporation source 500a may be set to spray a deposition material toward a target region different from a target region onto which a second nozzle tip 530b sprays the deposition material. In this case, one evaporation source 500 may cover various regions. Accordingly, according to the above-described embodiment, even when the number of evaporation sources 500 is small, the uniformity of the thin film of the substrate can be improved.

In addition, the number of nozzle tips 530 may be determined such that a thickness profile of the thin film of the substrate becomes uniform. The number of nozzle tips 530 may be determined according to the number of target regions onto which a deposition material is to be sprayed. The target region may be a region for which supplementation is determined to be required based on the thickness profile of the thin film of the substrate 50.

In addition, an opening area of the nozzle tip 530 may also be determined such that the thickness profile of the thin film of the substrate becomes uniform. Specifically, the opening area of the nozzle tip 530 may be determined based on an angular velocity and a spray angle for the rotation of the substrate 50. For example, since a film may become thinner as the angular velocity for the rotation of the substrate 50 becomes faster, an opening area of the nozzle tip 530 for a target region for which supplementation is required may be determined to have a larger diameter as compared to when the angular velocity for the rotation of the substrate 50 is slow. Meanwhile, the wider the opening area of the nozzle tip 530, the lower the flux density of the sprayed deposition material. Accordingly, a thickness of a material deposited at a target point may be decreased, and an area of a region to which a deposition material is deposited may be widened. Accordingly, the opening area of the nozzle tip 530 may be determined in consideration of a film thickness deviation and an area of a target region set such that a thickness profile of a thin film becomes uniform. As a result, the opening area of the nozzle tip 530 is determined in comprehensive consideration of an angular velocity for the rotation of the substrate 50 and a shape of a deposition profile for a target region (that is, a thickness of a material deposited at a target point and an area of a region on which a deposition material is deposited) according to the opening area of the nozzle tip 530, and a spray angle of the nozzle tip 530 may be determined based on the determined opening area. According to such a method, in the deposition system 5000, even when deposition is performed on substrates 50 that have various rotational angular velocities, a spray angle and an opening area of the nozzle tip 530 may be adjusted to uniformly perform deposition on each substrate 50.

Meanwhile, a plurality of evaporation sources 500 may be provided. In this case, the number of evaporation sources 500 may also be determined such that the thickness profile of the thin film of the substrate 50 becomes uniform. For example, the number of evaporation sources 500 may be determined to improve the uniformity of the thin film of the substrate 50 based on an area of the substrate 50, an angular velocity at which the substrate 50 rotates, the opening area of each of the plurality of nozzle tips 530, the number of the plurality of nozzle tips 530, and a magnitude of output power used to heat a deposition material.

In order to make a thickness profile of a thin film uniform, the spray angle, the number of nozzle tips, and the opening area of each of the plurality of evaporation sources 500a, 500b, and 500c may also be determined in various ways.

In addition, as shown in FIG. 5, the evaporation sources 500 may be determined to have the same spray angle, the same number of nozzle tips, the same opening area, and the same separation distance from the central axis 51 of the substrate 50. In this case, the evaporation sources 500 may spray a deposition material toward the same target region. For example, the nozzle tips 530a and 530b protruding from the first evaporation source 500a and the nozzle tips protruding from the second evaporation source 500b all spray the deposition material toward the central region and the outer region. According to the above-described embodiment, the thickness uniformity of a thin film can be easily improved by replacing the evaporation sources 500 in batches based on a thin film thickness profile result. In addition, even when an amount of a material deposited on a target region is decreased due to the occurrence of an error in an arrangement position of one of the evaporation sources 500, or the occurrence of a defect, such as a clogging phenomenon, in a function, the thickness uniformity may not be excessively reduced because other evaporation sources also spray a deposition material toward the target region.

Meanwhile, each of the evaporation sources 500 may be heated with the same power to evaporate a deposition material. In this case, there may be no difference in residual material between the plurality of evaporation sources 500 included in the deposition system 5000. Accordingly, even when a substrate deposition process proceeds for a long period of time, the uniformity of a thin film may not be degraded.

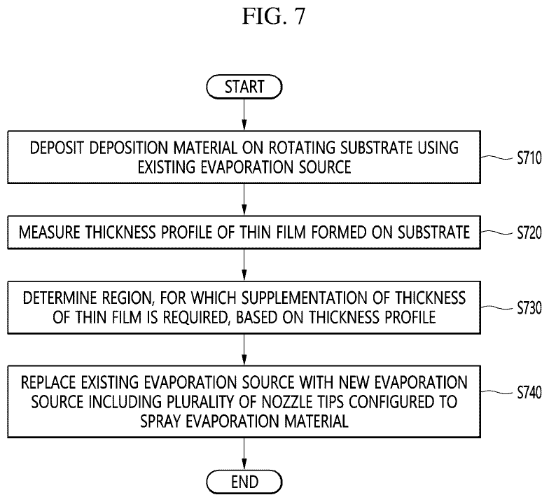

FIG. 7 is a flowchart of a method of replacing an evaporation source according to one embodiment of the present disclosure.

Referring to FIG. 7, the method of replacing an evaporation source includes operation S710 of depositing a deposition material on a rotating substrate using an existing evaporation source, operation S720 of measuring a thickness profile of a thin film formed on the substrate, operation S730 of determining a region, for which supplementation of a thickness of the thin film is required, based on the thickness profile, and an operation S740 of replacing the existing evaporation source with a new evaporation source including a plurality of nozzle tips that spray the deposition material. Here, the plurality of nozzle tips are set to thickly deposit the deposition material on the region for which supplementation is required so that a film thickness of the region, for which supplementation is required, and other regions become uniform.

According to the above-described embodiment, in the method of replacing an evaporation source, the existing evaporation source is replaced with the new evaporation source including the plurality of nozzle tips based on the thickness profile of the thin film measured during a substrate deposition process, thereby effectively improving the thickness uniformity of the thin film of the substrate after replacing the evaporation source.

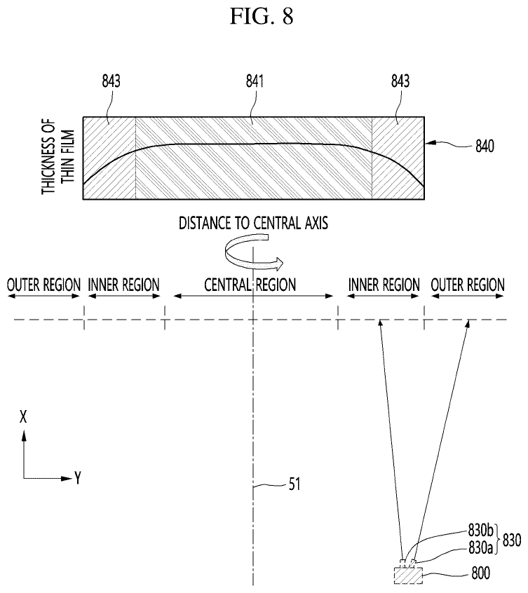

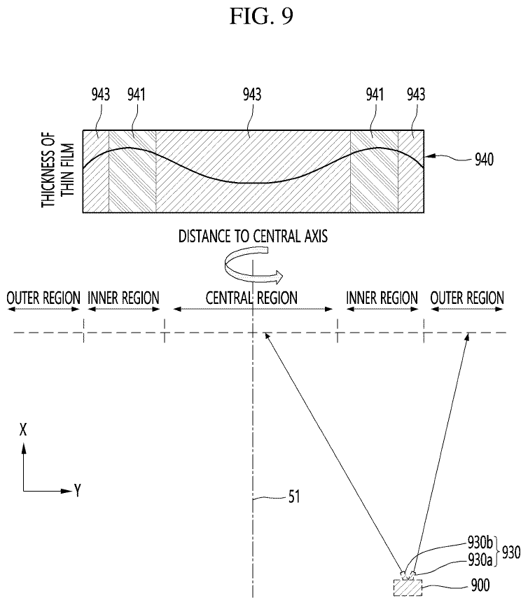

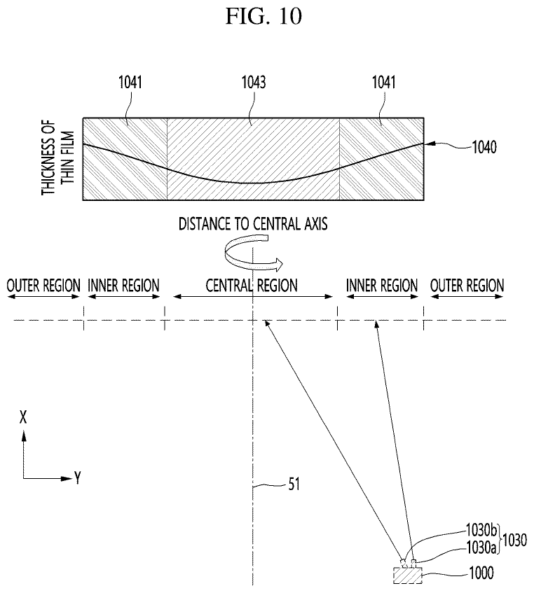

FIG. 8 is a view for describing a spray direction of a replacing evaporation source when a thick region is positioned in a central region. FIG. 9 is a view for describing a spray direction of a replacing evaporation source when a thick region is positioned in an inner region. FIG. 10 is a view for describing a spray direction of a replacing evaporation source when a thick region is positioned in an outer region.

Referring to FIG. 8, when a region 841 deposited on a substrate to be the thickest is positioned at a central portion of the substrate, a nozzle tip 830a provided on a replacing evaporation source 800 may spray a deposition material toward an outer region. Alternatively, one nozzle tip 830a provided in the replacing evaporation source 800 may spray the deposition material toward the outer region, and another nozzle tip 830b may spray the deposition material toward an inner region. As described above, when a region for which supplementation is required is a portion furthest from a center of the substrate, and the replacing evaporation source 800 sprays the deposition material toward the outside of the substrate, the thickness uniformity of a thin film of the entire substrate can be improved without a thin film of the inner region becoming excessively thick.

Referring to FIG. 9, when a region 941 deposited on a substrate to be the thickest is positioned at an inner region of the substrate, nozzle tips 930a and 930b provided in a replacing evaporation source 900 may spray a deposition material toward a central region and an outer region, respectively. As described above, when a region for which supplementation is required is the inner region and the replacing evaporation source 900 sprays the deposition material toward each of a center of the substrate and the outside of the substrate, the thickness uniformity of a thin film can be improved while preventing a center-drop or edge-drop phenomenon.

Referring to FIG. 10, when a region 1041 deposited on a substrate to be the thickest is positioned at a portion furthest from a center of the substrate, a nozzle tip 1030b provided in a replacing evaporation source 1000 may spray a deposition material toward a central region. Alternatively, one nozzle tip 1030b provided in the replacing evaporation source 1000 may spray the deposition material toward the central region, and another nozzle tip 1030a may spray the deposition material toward an outer region. As described above, when a region for which supplementation is required is a central portion of the substrate, and the replacing evaporation source 1000 sprays the deposition material toward the center of the substrate, the thickness uniformity of a thin film of the entire substrate can be improved without a thin film of the inner region becoming excessively thick.

According to the above-described embodiment, even when a thickness profile of a thin film has various shapes to be non-uniform, an existing evaporation source may be easily replaced with an evaporation source having a spray angle for improving the thickness uniformity of a thin film of a substrate.

In an evaporation source according to any one of the solutions of the present disclosure, a plurality of nozzle tips with different spray angles are provided, thereby simultaneously covering various target regions on which a deposition material should be deposited.

Among a plurality of nozzle tips provided in an evaporation source according to any one of the solutions of the present disclosure, opening areas of at least two nozzle tips are different, thereby adjusting an amount of a deposition material sprayed onto each of regions for which supplementation of a thickness of a thin film is required.

Since a deposition system according to any one of the solutions of the present disclosure includes a plurality of evaporation sources each heated with the same power to evaporate a deposition material, a difference in residual material between the plurality of evaporation sources may not occur.

Since a deposition system according to any one of the solutions of the present disclosure includes a plurality of evaporation sources of which at least two spray a deposition material toward the same region, thereby minimizing a degradation in the uniformity of a thin film even when an error occurs in the arrangement position of one of the evaporation sources or a defect occurs in a function thereof.

Since a deposition system according to any one of the solutions of the present disclosure includes an evaporation source including a plurality of nozzle tips, each of which an opening area is determined based on an angular velocity for the rotation of a substrate, even when the angular velocity for the rotation of the substrate changes as an area of the substrate changes in the same deposition system, the uniformity of a thin film of the substrate can be maintained or improved.

In a method of replacing an evaporation source according to any one of the solutions of the present disclosure, an existing evaporation source is replaced with a new evaporation source including a plurality of nozzle tips based on a thickness profile of a thin film measured during a substrate deposition process, thereby effectively improving the uniformity of a thin film of a substrate after replacing the evaporation source.

Although embodiments of the present disclosure have been described in more detail with reference to the accompanying drawings, the present disclosure is not necessarily limited to these embodiments, and various modifications may be made without departing from the technical spirit of the present disclosure. Accordingly, the embodiments disclosed in the present disclosure are not intended to limit the technical idea of the present disclosure, but are for illustrative purposes, and the scope of the technical idea of the present disclosure is not limited by these embodiments. Accordingly, it should be understood that the above-described embodiments are exemplary in all respects and not restrictive. The spirit and scope of the present disclosure should be interpreted by the appended claims and encompass all equivalents 5 falling within the scope of the appended claims.

What is claimed is:

1. An evaporation source comprising:
a crucible having a cylinder shape and configured to accommodate a deposition material; and
a nozzle member disposed on an upper end of the crucible,
wherein the nozzle member includes a plurality of nozzle tips protruding from an upper surface of the nozzle member in a direction in which the deposition material is sprayed.

2. The evaporation source of claim 1, wherein a spray angle, which is defined as an angle between a protruding direction of each of the plurality of nozzle tips and a direction perpendicular to the upper surface of the nozzle member, and a position of each of the plurality of nozzle tips are determined such that a thickness profile of a thin film, which is formed by depositing the deposition material sprayed through the plurality of nozzle tips, becomes uniform.

3. The evaporation source of claim 2, wherein the spray angles of at least two of the plurality of nozzle tips are different.

4. The evaporation source of claim 1, wherein protruding directions of the plurality of nozzle tips are positioned on one plane.

5. The evaporation source of claim 1, wherein the plurality of nozzle tips are arranged in a line on the upper surface of the nozzle member.

6. The evaporation source of claim 1, wherein at least one of the plurality of nozzle tips is disposed in a different column from columns in which other nozzle tips are arranged.

7. The evaporation source of claim 1, wherein opening areas of the plurality of nozzle tips are equal to each other, and
the opening area is an area of a cross section perpendicular to a protruding direction of each of the plurality of nozzle tips.

8. The evaporation source of claim 1, wherein opening areas of at least two of the plurality of nozzle tips are different, and
the opening area is an area of a cross section perpendicular to a protruding direction of each of the plurality of nozzle tips.

9. A deposition system for depositing a deposition material on a substrate, the deposition system comprising
an evaporation source including a plurality of nozzle tips configured to spray a deposition material toward a plurality of target regions,
wherein a spray angle of at least one of the plurality of nozzle tips is set to spray the deposition material toward a target region different from a target region onto which other nozzle tips spray the deposition material.

10. The deposition system of claim 9, wherein the evaporation source is provided as a plurality of evaporation sources, and
each of the plurality of evaporation sources is heated with the same power to evaporate the deposition material.

11. The deposition system of claim 10, wherein the spray angles of at least two of the plurality of evaporation sources are equal to each other.

12. The deposition system of claim 9, wherein the spray angle of each of the plurality of nozzle tips is determined according to Equation 1 below:
$$θ = {tan}^{- 1} ( \frac{{x}_{e} - {x}_{t}}{L} ) \qquad [ Equation 1 ]$$
wherein 0 denotes the spray angle which is an angle between a protruding direction of the nozzle tip and a direction perpendicular to an upper surface of the evaporation source including the nozzle tip,
xₑ denotes an x-axis coordinate at which the evaporation source is positioned on a plane including a central axis and the evaporation source,
xₜ is denotes an x-axis coordinate at which a target point is positioned on a plane including the central axis and the evaporation source, and
L denotes a distance between the evaporation source and the substrate.

13. The deposition system of claim 12, wherein an opening area of each of the plurality of nozzle tips is determined based on an angular velocity for a rotation of the substrate and the spray angle and is an area of a cross section perpendicular to the protruding direction of the nozzle tip.

14. A method of replacing an evaporation source, the method comprising:
depositing a deposition material on a rotating substrate using an existing evaporation source;
measuring a thickness profile of a thin film formed on the substrate;
determining a region, for which supplementation of a thickness of the thin film is required, based on the thickness profile; and
replacing the existing evaporation source with a new evaporation source including a plurality of nozzle tips configured to spray the deposition material,
wherein the plurality of nozzle tips are set to thickly deposit the deposition material on the region for which supplementation is required so that a film thickness of the region, for which supplementation is required, and other regions become uniform.

15. The method of claim 14, wherein, when a region deposited on the substrate to be the thickest is positioned at a central portion of the substrate, the replacing includes setting a spray angle of the replacing evaporation source such that at least one of the plurality of nozzle tips sprays the deposition material toward the outside of the substrate.

16. The method of claim 14, wherein, when a region deposited on the substrate to be the thickest is positioned in an inner region of the substrate rather than a central portion of the substrate, the replacing includes setting a spray angle of the replacing evaporation source such that at least two of the plurality of nozzle tips spray the deposition material toward the central portion of the substrate and the outside of the substrate, respectively.
